(19) United States
(12) Patent Application Publication
(10) Pub. No.: US 2005/0169330 A1
(43) Pub. Date: Aug. 4, 2005

(54) Laser annealing apparatus and annealing method of semiconductor thin film

(76) Inventors: Mikio Hongo, Yokohama (JP); Akio Yazaki, Fuchu (JP); Mutsuko Hatano, Kokubunji (JP); Takeshi Noda, Mobara (JP); Yukio Takasaki, Kawasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/987,003

(22) Filed: Nov. 15, 2004

(30) Foreign Application Priority Data
Jan. 30, 2004 (JP) 2004-022433

(51) Int. Cl. H01S 3/00; H01L 21/00; H01L 21/84; H01L 21/76; C30B 1/00; H01L 21/20; H01L 21/36

(52) U.S. Cl. 372/38.02; 438/487; 438/166

(57) ABSTRACT

When a laser bean temporally modulated in amplitude by a modulator is shaped into a long and narrow beam by a beam shaper, the scanning-direction size of the long and narrow beam shaped by the beam shaper is selected to be in a range of from 2 to 10 microns, preferably in a range of from 2 to 4 microns and the scanning speed of the beam is selected to be in a range of from 300 to 1000 mm/s, preferably in a range of from 500 to 1000 m/s. As a result, damage of the silicon thin film can be suppressed while energy utilizing efficiency of the laser beam can be improved. Accordingly, laterally grown crystals (belt-like crystals) improved in throughput can be obtained on a required region of a substrate scanned and irradiated with the laser beam.

### BACKGROUND OF THE INVENTION

The present invention relates to a laser annealing method and a laser annealing apparatus adapted for improvement of film quality and magnification or single-crystallization of crystal grains by applying a laser beam on an amorphous or polycrystalline semiconductor film formed on an insulating substrate.

At present, in a display device such as a liquid crystal display device or an organic electroluminescence (EL) display device, an image is formed by switching of pixel transistors (thin-film transistors) each formed from an amorphous or polycrystalline silicon film on a substrate such as a glass substrate or a fused quartz substrate. If a driver circuit for driving each pixel transistor can be formed together with the pixel transistor on the substrate, there is expectation that reduction in production cost and improvement in reliability will be attained remarkably. When a silicon film serving as an active layer of a transistor (thin film transistor) for forming the driver circuit is made of amorphous silicon, it is however difficult to produce a circuit requiring a high speed and a high function because the performance of the thin film transistor represented by mobility is low.

Thin film transistors of high mobility are required for production of such high-speed high-function circuits. To achieve the high mobility of the thin film transistors, it is necessary to improve the crystallinity of the silicon thin film. As a method for improving the crystallinity, excimer laser annealing has heretofore attracted public attention. This method intends to improve mobility by irradiating an amorphous silicon film formed on an insulating substrate such as a glass substrate with an excimer laser beam to transform the amorphous silicon film into a polycrystalline silicon film. The polycrystalline film obtained by excimer laser irradiation is however still insufficient in performance for application to the driver circuit etc. for driving the liquid crystal panel because the crystal grain size of the polycrystalline film is in a range of from the order of tens of nm to the order of hundreds of nm.

As a conventional technique for solving this problem, a method has been disclosed in Patent Document 1. In the method, a continuous-wave (CW) laser beam temporally modulated in amplitude is condensed linearly and applied on a substrate while scanned at a high speed to thereby grow crystals laterally in the scanning direction to form so-called belt-like crystals. This method intends to improve mobility greatly in the following manner. After the whole surface of the substrate is poly-crystallized by excimer laser annealing, only a region in which a driver circuit will be formed is scanned with the laser beam in a direction coincident with the current path (drain-source direction) of a transistor to be formed. As a result, crystal grains are grown laterally so that there is no grain boundary crossing the current path. Patent Document 2 is another related technical document.
[Patent Document 1] Japanese Patent Laid-Open No. 2003-124136
[Patent Document 2] Japanese Patent Laid-Open No. 2003-86505

### SUMMARY OF THE INVENTION

The present invention intends to improve the conventional technique. That is, in the conventional technique, there is a problem that the energy loss is large because a multi-lens array or kaleidoscope complex in structure is used as a homogenizer (beam shaper) for shaping a solid-state laser beam such as the second harmonic of a CW YAG laser beam used into a long and narrow beam or a rotary diffusing plate is used for reducing coherence.

In addition, there is a problem that the silicon film is apt to be damaged by change in energy because the energy condition range in which good laterally grown crystals can be obtained is narrow though a required region is irradiated with the laser beam at a scanning speed of about 100 mm/s after the laser beam is shaped into a long and narrow beam so that the short dimension of the laser beam is reduced to about 20 microns.

To solve the problems in the background art, an object of the invention is to provide a laser annealing method and a laser annealing apparatus in which a laser beam is shaped into a long and narrow beam efficiently without energy loss so that a silicon film exhibiting high mobility in a wide energy condition range can be formed.

To achieve the foregoing object, in the laser annealing method and laser annealing apparatus according to the invention, a diffractive optical element or a combination of a Powell's lens and a cylindrical lens is used as a homogenizer (beam shaper) Moreover, the shaped beam is reductively projected by an imaging lens so that a long and narrow beam having a required short dimension (or scanning-direction dimension) can be obtained. A value of from 2 to 10 microns or preferably a value of from 2 to 4 microns can be achieved as the scanning-direction dimension of the beam obtained on this occasion. The scanning speed is selected to be preferably in a range of from 300 to 1000 mm/s, further preferably in a range of from 500 to 1000 mm/s. Incidentally, the invention is not limited to the aforementioned configuration and various changes may be made without departing from the spirit of the invention.

In the laser annealing method and laser annealing apparatus according to the invention, a laser beam can be shaped into a long and narrow beam with a small energy loss when a diffractive optical element simple in structure or a combination of a Powell's lens and a cylindrical lens is used as a homogenizer (beam shaper).

In addition, when the shaped beam is reductively projected by an imaging lens, a long and narrow beam having a required short dimension (or scanning-direction dimension) can be obtained. A value of from 2 to 10 microns or preferably a value of from 2 to 4 microns can be achieved as the short dimension of the beam obtained on this occasion. When the scanning speed is selected to be preferably in a range of from 300 to 1000 mm/s, further preferably in a range of from 500 to 1000 mm/s, good annealing can be performed so that belt-like crystals can be formed in the laser-irradiated region.

According to the invention, a silicon film of high mobility can be obtained stably, so that a thin film semiconductor device substrate of good performance can be obtained. When the invention is applied to production of a display device represented by a liquid crystal display device or an organic EL display device, so-called “system-in” can be achieved.

### BRIEF DESCRIPTION OF THE DRAWINGS

These and other features, objects and advantages of the present invention will become more apparent from the following description when taken in conjunction with the accompanying drawings wherein:

FIG. 1 is a diagram showing the configuration of a laser annealing apparatus according to an embodiment of the invention;

FIGS. 2A and 2B are views for explaining a diffractive optical element type homogenizer which can be applied to the laser annealing apparatus according to an embodiment of the invention;

FIGS. 3A and 3B are views for explaining a Powell's lens type homogenizer which can be applied to the laser annealing apparatus according to an embodiment of the invention;

FIG. 4 is a graph showing a power density range in which good annealing can be performed when the short dimension of a shaped beam is changed;

FIG. 5 is a graph showing a power density range in which good annealing can be performed when the scanning speed of the shaped beam is changed;

FIG. 6 is a graph showing a lower limit of average energy density in which good annealing can be performed when the short dimension of the shaped beam is changed;

FIGS. 7A to 7C are views for explaining a laser annealing method according to an embodiment of the invention;

FIGS. 8A and 8B are views for explaining a state in which belt-like crystals are formed on an amorphous silicon film substrate irradiated with the shaped beam;

FIGS. 9A and 9B are views for explaining a process of forming belt-like crystals on an amorphous silicon film substrate by irradiating the amorphous silicon film substrate with the shaped beam;

FIGS. 10A and 10B are views for explaining a process of forming a thin film transistor from the belt-like crystals formed by the process shown in FIGS. 9A and 9B;

FIG. 11 is a view for explaining a substrate formed from a plurality of panels; and

FIGS. 12A to 12D are views for explaining various arrangements of belt-like crystal regions represented by drain driver circuit regions in one panel.

### DETAILED DESCRIPTION OF PREFERRED EMBODIMENTS

The present invention will be described below in detail with reference to the drawings showing respective embodiments thereof.

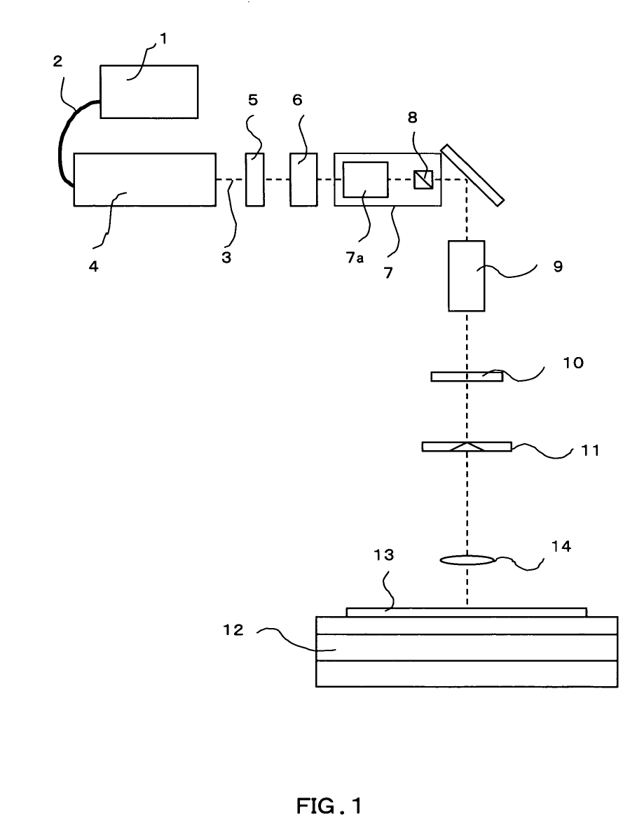

FIG. 1 is a diagram showing the optical configuration of a laser annealing apparatus according to an embodiment of the invention. The annealing apparatus comprises a laser oscillator 4, a shutter 5, a continuously variable transmittance neutral-density (ND) filter 6, a modulator 7, a beam expander (beam reducer) 9, a beam shaper 10, a rectangular opening slit 11, and an imaging lens 14. The laser oscillator 4 is connected to an excitation laser diode (LD) 1 by a fiber 2 and generates a continuous-wave (CW) laser beam 3. The shutter 5 switches the laser beam 3 on and off. The continuously variable transmittance ND filter 6 controls the energy of the laser beam 3. The modulator 7 temporally modulates in amplitude the laser beam 3 output from the laser oscillator 4 to achieve temporal amplitude modulation of pulsation or energy. The beam expander (beam reducer) 9 controls the beam diameter of the laser beam 3. The beam shaper 10 shapes the laser beam 3 into a long and narrow beam such as a linear beam, a rectangular beam, an elliptic beam or an ellipsoidal beam. The rectangular opening slit 11 adjusts the long dimension of the shaped laser beam 3 to a predetermined size. The imaging lens 14 is provided so that an image of the long and narrow laser beam shaped by the beam shaper 10 is reductively projected on a substrate 13 placed on an XY stage 12.

In this embodiment, the modulator 7 includes an electro-optical modulator (hereinafter referred to as EO modulator) 7a, and a polarized beam splitter 8 by way of example. The configuration of the modulator 7 need not be limited thereto.

Next, the operation and function of each portion will be described in detail. It is preferable that the CW laser beam 3 has a wavelength absorbable to an amorphous or polycrystalline silicon thin film which is a subject of annealing. That is, it is preferable that the wavelength of the CW laser beam 3 ranges from an ultraviolet light wavelength to a visible light wavelength. More specifically, an Ar or Kr laser beam and its second harmonic, second and third harmonics of an Nd:YAG, Nd:YVO₄ or Nd:YLF laser beam, etc. can be used as the CW laser beam 3. Among these, the second harmonic (wavelength: 532 nm) of a laser diode (LD)-pumped Nd:YAG laser beam or the second harmonic (wavelength: 532 nm) of an LD-pumped Nd:YVO₄ laser beam is most preferred in consideration of magnitude of the output and stability. The following description is based on the case where the second harmonic of an LD-pumped Nd:YVO₄ laser beam is used as the CW laser beam 3.

The laser beam 3 oscillated by the laser oscillator 4 is switched on/off by the shutter 5. That is, while the laser oscillator 4 always oscillates the laser beam 3 with constant output, the shutter 5 is ordinarily closed (as an off state) so that the laser beam 3 is blocked off by the shutter 5. Only when irradiation with the laser beam 3 is required, the shutter 5 is opened (as an on state) so that the laser beam 3 is output from the shutter 5. Although the on/off control of the laser beam 3 can be performed by turning the excitation laser diode 1 on/off, the on/off control is undesirable for keeping the stability of the laser output high. When irradiation with the laser beam 3 needs to be interrupted from a point of view of safety in case of emergency in another situation, the shutter 5 can be closed.

The laser light 3 passed through the shutter 5 is made incident on the modulator 7 after transmitted through the continuously variable transmittance ND filter 6 used for controlling the output. A filter capable of transmitting the laser beam but incapable of rotating the direction of polarization is used preferably as the continuously variable transmittance ND filter 6. Incidentally, when an acousto-optical (AO) modulator not affected by the direction of polarization as will be described later is used as the modulator 7, this rule does not apply to the AO modulator. The EO modulator 7a is provided so that when a voltage is applied to a Pockels cell (crystal) (designated by the reference numeral 7a in FIG. 1) through a driver (not shown), the direction of polarization of the laser beam 3 transmitted through the crystal is rotated. The polarized beam splitter 8 disposed in the rear of the crystal transmits only the P-polarized light component of the laser beam 3 but deflects the S-polarized light component of the laser beam 3 by 90 degrees. In this manner, the on/off control and output control of the laser beam 3 can be performed. Incidentally, the output control based on the EO modulator 7a is not a function essential to the embodiment. If the EO modulator 7a can perform only the on/off control of the laser beam 3, the effect of the invention can be obtained sufficiently.

A voltage V1 for rotating the direction of polarization of the laser beam 3 to make the P-polarized light component of the laser beam 3 incident on the polarized beam splitter 8 and a voltage V2 for rotating the direction of polarization of the laser beam 3 to make the S-polarized light component of the laser beam 3 incident on the polarized beam splitter 8 are applied alternately or a voltage changing between V1 and V2 voluntarily is applied to thereby temporally modulate the laser beam 3. Although the EO modulator 7a shown in FIG. 1 has been explained in the case where a Pockels cell and a polarized beam splitter 8 are combined, any other polarizing element may be used as a substitute for the polarized beam splitter. Although FIG. 1 has shown the case where the Pockels cell is called EO modulator 7a, a combination of the Pockels cell and the polarized beam splitter 8 (or any other polarizing element) may be generically called EO modulator because the Pockels cell inclusive of the polarizing element may be available as an EO modulator on the market.

An acousto-optical (AO) modulator may be used as another example of the modulator 7. Generally, the driving frequency of the AO modulator is lower than that of the EO modulator. In addition, the diffractive efficiency of the AO modulator is from 70% to 90% as much as that of the EO modulator, that is, the diffractive efficiency of the AO modulator is lower than that of the EO modulator. The AO modulator however has such characteristic that the on/off control of the laser beam can be performed even in the case where the laser beam is not linearly polarized. Accordingly, the AO modulator has no problem even in the case where a filter of the type rotating the direction of polarization of the laser beam transmitted through the filter is used as the continuously variable transmittance ND filter 6. When the modulator 7 such as the EO modulator 7a (inclusive of the polarized beam splitter 8) or an AO modulator is used in this manner, a laser beam having an arbitrary waveform (temporal energy change) at arbitrary timing can be obtained from the CW laser beam. That is, required temporal modulation can be performed.

The temporally modulated in amplitude laser beam 3 is made incident on the beam shaper 10 after the beam diameter of the laser beam 3 is controlled by the beam expander (or beam reducer) 9 which is provided for controlling the beam diameter. The beam shaper 10 is an optical element for shaping the laser beam 3 into a long and narrow beam. Generally, a gas or solid state laser beam cannot be used directly for laser annealing in the invention because it has a Gaussian energy distribution. If the output of the oscillator is sufficiently high, a nearly uniform energy distribution can be obtained when only a relatively uniform portion is extracted from the center of the beam after the beam diameter is widened sufficiently. Large part of energy, however, goes to waste because the peripheral portion of the beam must be discarded. To eliminate this disadvantage, the beam shaper 10 is used for transforming the Gaussian distribution into a uniform distribution (top flat).

A diffractive optical element 22 can be used as the beam shaper 10. The diffractive optical element 22 is produced as follows. Step portions having a fine difference in level between the step portions are formed in a substrate such as a quartz substrate by a photo-etching process. Diffraction patterns formed by a laser beam transmitted through the step portions respectively are synthesized on an image formation plane (a plane of the rectangular opening slit 11). As a result, a required energy distribution can be obtained on the image formation plane (the plane of the rectangular opening slit 11).

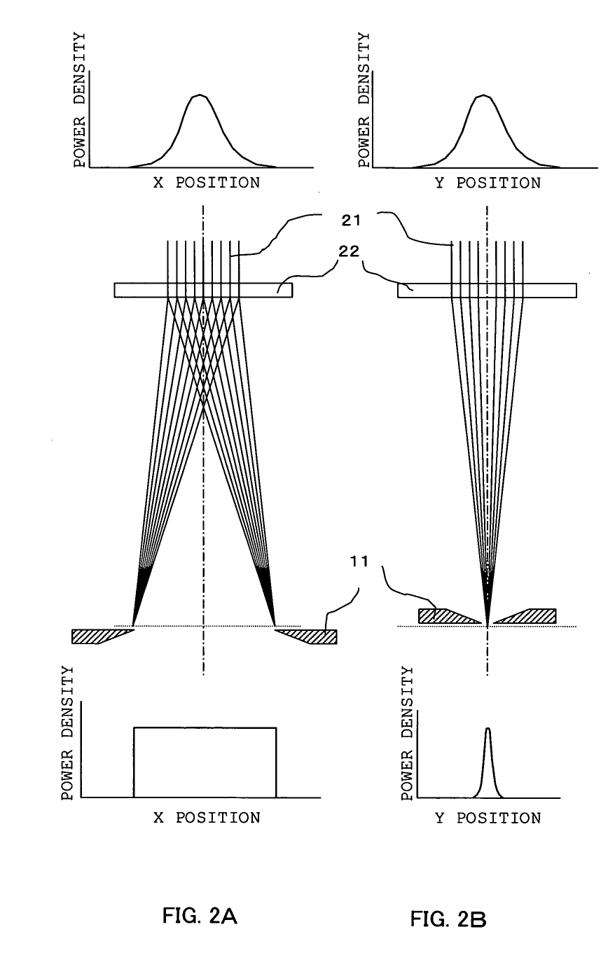

FIGS. 2A and 2B are views for explaining a diffractive optical element type homogenizer which can be used in the laser annealing apparatus according to an embodiment of the invention. The diffractive optical element 22 used here is designed/produced so that when a laser beam 21 having a Gaussian power density distribution as shown in FIGS. 2A and 2Bis incident on the diffractive optical element 22, the laser beam 21 is condensed to have a power density distribution which is uniform in one direction (x direction shown in FIG. 2A) but Gaussian in a direction (y direction shown in FIG. 2B) perpendicular to the x direction. A uniform intensity distribution of about ±3% is obtained in the long dimension of the laser beam when the diffractive optical element 22 is used.

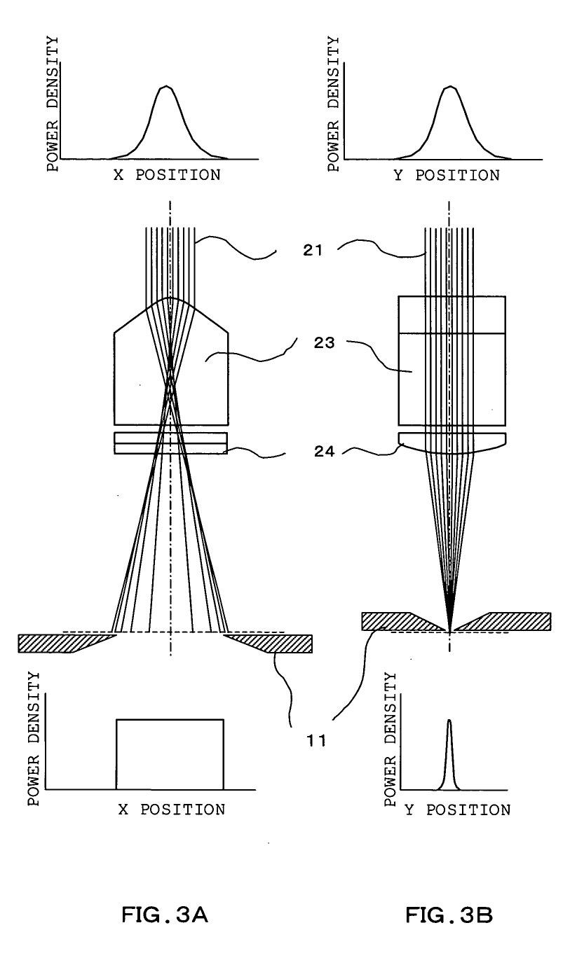

FIGS. 3A and 3B are views for explaining a Powell's lens type homogenizer which can be used in the laser annealing apparatus according to an embodiment of the invention. A combination of a Powell's lens 23 and a cylindrical lens 24 shown in FIGS. 3A and 3B can be used in place of the diffractive optical element 22 as the beam shaper 10. The Powell's lens 23 is a kind of cylindrical lens. When a laser beam 21 having a Gaussian power density distribution as shown in FIG. 3A is incident on the Powell's lens 23, an image of the laser beam is formed on a projection plane (a plane of the rectangular opening slit 11 in FIG. 1) so that a high energy density portion in the center of the laser beam becomes sparse while a low energy density portion in the periphery of the laser beam becomes dense. If the Powell's lens 23 is used singly, the energy distribution does not change in a direction perpendicular to the plane shown in FIG. 3A, that is, in a direction perpendicular to the paper surface. Therefore, the laser beam 21 is condensed by the cylindrical lens 24 as shown in FIG. 3B.

As a result, a long and narrow beam which has a uniform energy distribution in the direction of the long dimension of the laser beam (i.e. in the direction shown in FIG. 3A) but has a Gaussian energy distribution in the direction of the short dimension of the laser beam (i.e. in the direction shown in FIG. 3B) is formed on the plane of the rectangular opening slit 11. A uniform intensity distribution of about ±5% is obtained in the direction of the long dimension of the laser beam when the Powell's lens 23 is used.

If necessary, large energy density change portions or skirt portion in the periphery of the beam in the direction of the long dimension of the beam (higher-order diffracted light in the case of the diffractive optical element) can be shaded by the rectangular opening slit 11. In this case, an energy distribution having a precipitous leading edge is obtained.

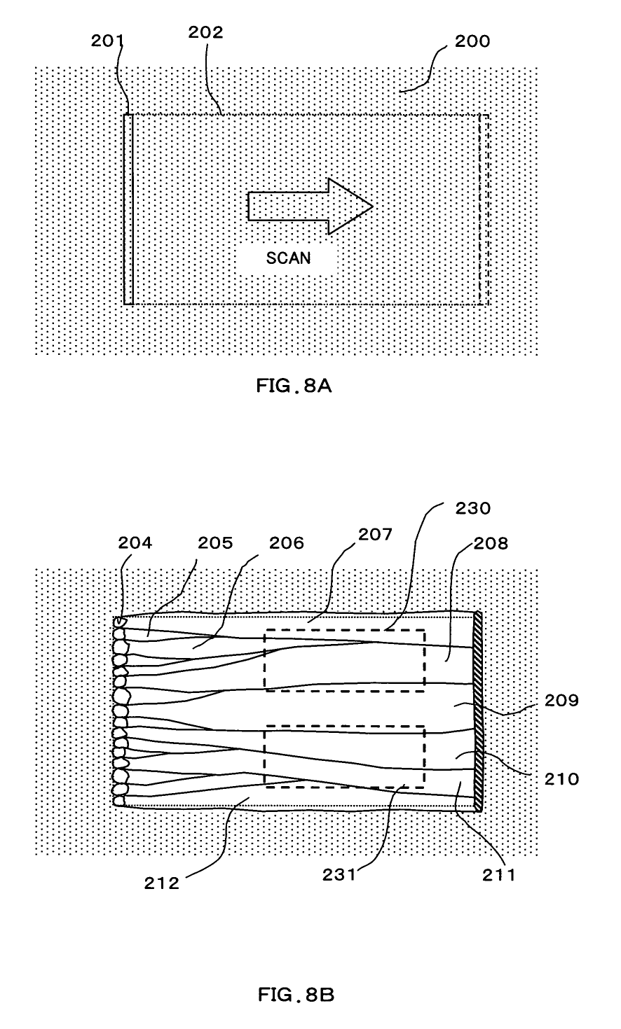

The behavior of an amorphous silicon thin film in the case where the CW laser beam temporally modulated in amplitude and shaped into a long and narrow beam is applied on the amorphous silicon thin film while scanned will be described with reference to FIGS. 8A and 8B.

FIGS. 8A and 8B are views for explaining a state in which belt-like crystals are formed on the amorphous silicon film substrate irradiated with the shaped beam. As described above, in this embodiment, a substrate 200 having an amorphous silicon thin film formed on a glass substrate is used as a subject of annealing. As shown in FIG. 8A, a laser beam 201 condensed into a long and narrow shape is applied on a region 202 while scanned on the amorphous silicon film 200. When a laser beam with proper power density is applied, amorphous silicon included in a region 202 irradiated with the laser beam is melted though the other region than the laser-irradiated region 202 of the amorphous film 200 remains as it is.

Then, the laser beam 201 is moved out (or traveled) the melted amorphous silicon, so that the melted amorphous silicon is solidified/crystallized rapidly. On this occasion, cooling/solidification starts from silicon in the first melted region as shown in FIG. 8B, so that microcrystals 204 oriented in random directions are formed. The respective microcrystals grow continuously in the scanning direction of the laser beam but each microcrystal has its own growth rate depending on the crystal orientation. As a result, only crystal grains having the crystal orientation exhibiting the highest growth rate can grow continuously. That is, as shown in FIG. 8B, the growth of a crystal grain 205 having the crystal orientation exhibiting a low growth rate is suppressed by the growth of crystal grains 206 and 207 adjacent to the crystal grain 205 and each having the crystal orientation exhibiting a high growth rate, so that crystal growth of the crystal grain 205 stops.

While the crystal grain 206 having the crystal orientation exhibiting an intermediate growth rate grows continuously, the growth of the crystal grain 206 is suppressed by the growth of crystal grains 207 and 208 each having a growth rate higher than that of the crystal grain 206, so that the growth of the crystal grain 206 stops. Finally, the crystal grains 207 and 208 each having the crystal orientation exhibiting the highest growth rate grow continuously. Incidentally, the crystal grains do not grow endlessly. When the growth of the crystal grains reaches a length of from about 5 to 50 microns, the growth of the crystal grains is suppressed by the growth of crystal grains which begin to grow newly. As a result, crystal grains each having a width of from 0.2 to 2 microns and a length of from 5 to 50 microns are obtained.

The crystal grains 207, 208, 209, 210, 211 and 212 which have continued the crystal growth to the last are independent crystal grains in the strict sense. The crystal grains 207, 208, 209, 210, 211 and 212, however, substantially have the same crystal orientation. A melted and re-crystallized portion of the crystal grains is formed as a polycrystalline film composed of belt-like crystal grains which are formed in such a manner that silicon crystals grow laterally. The polycrystalline film can be practically substantially regarded as a single crystal (pseudo single crystal). In addition, the surface roughness of the polycrystalline film after laser annealing is not larger than 10 nm, that is, the polycrystalline film is very flat.

When the laser beam 201 is applied on the amorphous silicon thin film in the aforementioned manner, regions irradiated with the laser beam are annealed like islands (tiles) so that only crystal grains having a specific crystal orientation grow to form a region which is in a polycrystalline state in the strict sense but has properties substantially close to those of a single crystal. Particularly in a direction not crossing any grain boundaries, the polycrystalline region can be substantially regarded as a single crystal. On this occasion, a value of 400 cm²/Vs or higher, typically a value of 450 cm²/Vs is obtained as the mobility of the silicon film.

The same result as described above can be obtained in the case where a polycrystalline film is formed on a glass substrate. Because poly-crystal is present in the portion where laser irradiation starts, crystal grains of the poly-crystal serve as seed crystals respectively so that the crystals grow laterally in the scanning direction of the laser beam in the same manner as in the case of an amorphous state. The laterally grown belt-like crystals are substantially the same as those formed from the amorphous state.

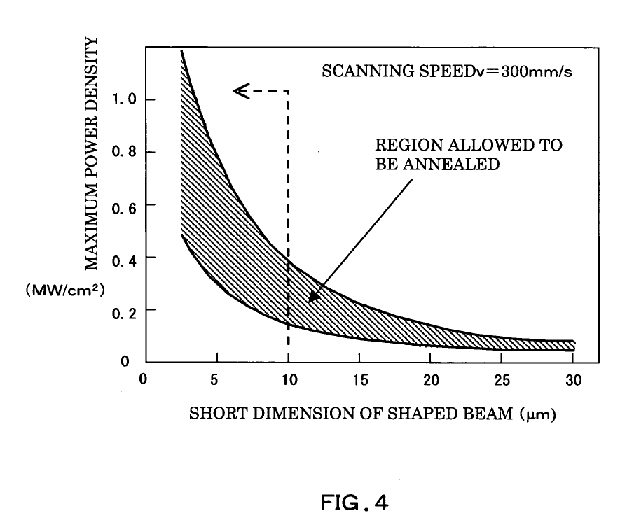

A result of an annealing test will be described in the case where the annealing test is performed in the condition that a 50 nm-thick amorphous or polycrystalline silicon film formed on a glass substrate through an insulating film is irradiated with a shaped beam while the short dimension and scanning speed of the shaped beam are changed. First, FIG. 4 shows a power density range in which good belt-like crystals can be formed from the amorphous silicon film when the short dimension of the laser beam shaped like a long and narrow beam is changed while the scanning speed is set by a constant value of 300 mm/s.

FIG. 4 is a graph showing a power density range in which good annealing can be performed when the short dimension of the shaped beam is changed. In FIG. 4, the horizontal axis expresses the short dimension (width) of the laser beam shaped like a long and narrow beam in terms of microns, and the vertical axis expresses the maximum power density of the laser beam shaped like a long and narrow beam in terms of MW/cm². The maximum power density shown in FIG. 4 is power density in the center of the beam in the direction of the short dimension. Because power density has a Gaussian distribution in the direction of the short dimension of the beam, the maximum power density is expressed as a value twice as much as the average power density.

In a laser beam having a Gaussian distribution profile, the average power density is defined as a value which is obtained by averaging all power in the beam diameter (beam width) when a portion of 13.5% is regarded as the beam diameter (e.g. the beam width in the direction of the short dimension of the beam) on the assumption that the maximum power density (power density in the center) is 1. Half of the maximum power density is the average power density in the case of the Gaussian distribution. The term “good” means that crystals grow laterally in the scanning direction of the laser beam to form large belt-like crystal grains when the silicon film irradiated with the laser beam is melted and re-solidified.

In FIG. 4, the hatched region shows a range in which belt-like crystals can be produced actually. In the condition that the maximum power density is lower than the hatched region, when the silicon film irradiated with the laser beam is amorphous, poly-crystallization can be made but lateral growth cannot be made so that the crystal grains are small, that is, in a so-called microcrystalline state. When the silicon film irradiated with the laser beam is a polycrystalline film formed by irradiation with an excimer laser beam, a solid-state pulse laser beam or the like, the lower limit of the maximum power density in which belt-like crystals can be formed shifts by 5-10% to the high power density side. In this case, in the condition that power density is low, crystal growth little occurs because the silicon film cannot be melted perfectly. On the other hand, in the condition that the maximum power density is higher than the hatched region, the silicon film is not uniform any longer because the melted silicon is gathered by surface tension regardless of the kind of the silicon film irradiated with the laser beam.

It is apparent from FIG. 4 that required power density increases but the power density range is widened rapidly as the short dimension of the beam decreases. In FIG. 4, when the short dimension of the shaped beam is 3. 0microns, the maximum power density range in the center of the beam allowing good annealing has a lower limit of 0.45 MW/cm² and an upper limit of 1.04 MW/cm². When a 10 W-output oscillator is used as the laser oscillator 4 while the short dimension of the beam shaped like a long and narrow beam is set by 3.0 microns, the long dimension of the beam can be set to be about 500 microns if reflection loss on a surface of an optical element in the middle is taken into account.

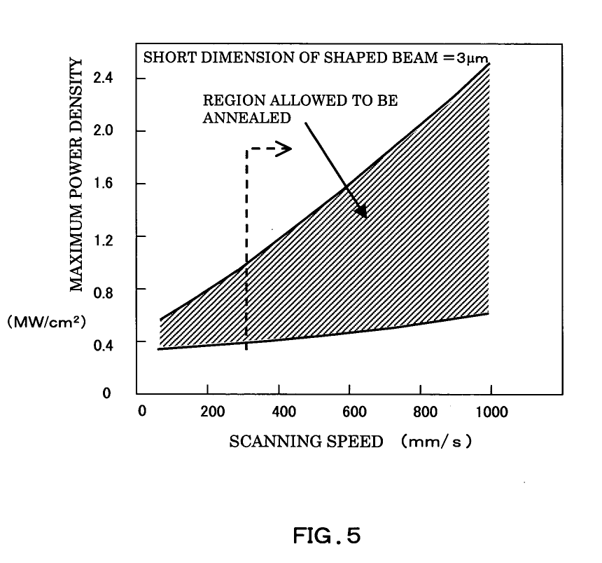

Next, FIG. 5 shows a power density range in which good belt-like crystals can be formed from the amorphous silicon film when the scanning speed is changed while the short dimension of the laser beam shaped like a long and narrow beam is set by a constant value of 3.0 microns.

FIG. 5 is a graph showing a power density range in which good annealing can be performed when the scanning speed of the shaped beam is changed. In FIG. 5, the horizontal axis expresses the scanning speed of the laser beam in terms of mm/s, and the vertical axis expresses the power density of the laser beam in terms of MW/cm². The power density shown in FIG. 5 is power density in the center in the direction of the short dimension of the laser beam like FIG. 4. Because the power density in the direction of the short dimension of the laser beam has a Gaussian distribution, the power density shown in FIG. 5 is twice as much as the average power density, that is, the power density shown in FIG. 5 is maximum power density. Like the description in FIG. 4, the term “good” means that crystals grow laterally in the scanning direction of the laser beam to form large crystal grains, that is, belt-like crystal grains when the silicon film irradiated with the laser beam is melted and re-solidified.

In FIG. 5, the hatched region shows a range in which good annealing can be achieved. In the condition that the maximum power density is lower than the hatched region, when the silicon film irradiated with the laser beam is amorphous, poly-crystallization can be made but the crystal grains are small, that is, in a so-called microcrystalline state. In the condition that the power density is further lower, the silicon film cannot be melted so that the silicon film is kept amorphous. In the test range, the lower limit of the power density allowing good annealing increases slightly but with no large change as the scanning speed increases.

On the other hand, in the condition that the maximum power density is higher than the hatched region, the silicon film is not uniform any longer because the melted silicon is gathered by surface tension regardless of the kind of the silicon film irradiated with the laser beam. It is apparent from FIG. 5 that required power density increases slightly but the power density causing gathering increases rapidly as the scanning speed increases. For this reason, it is consequently apparent that the power density range allowing good annealing is widened rapidly as the scanning speed increases. As shown in FIG. 5, when scanning is performed at a high speed, the upper limit of good power density increases rapidly. This is because the time in which silicon is melted can be shortened by high-speed scanning to prevent the silicon film from being gathered.

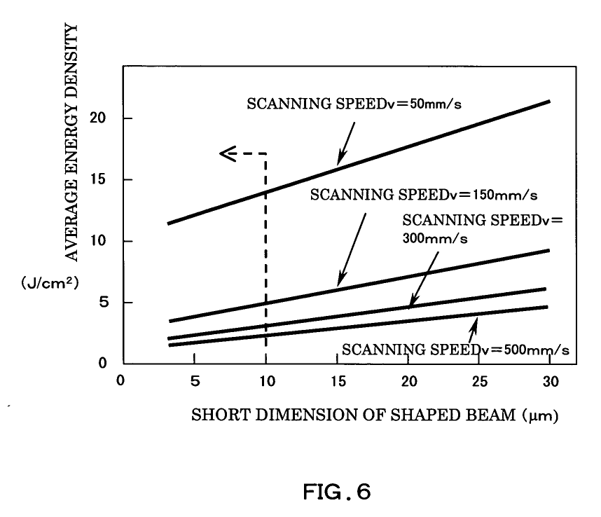

Next, FIG. 6 shows the lower limit of average energy density in which good annealing can be performed, that is, crystals can grow laterally in the scanning direction of the laser beam to form belt-like crystal grains when the silicon film is melted and re-solidified in the case where the short dimension of the laser beam shaped like a long and narrow beam is changed. In FIG. 6, the lower limit of average energy density is expressed with the scanning speed used as a parameter.

FIG. 6 is a graph showing the lower limit of average energy density in which good annealing can be performed in the case where the short dimension of the shaped beam is changed. In FIG. 6, four graphic patterns measured when the scanning speed v is changed to 50 mm/s, 150 mm/s, 300 mm/s and 500 mm/s are shown in descending order. In FIG. 6, the horizontal axis expresses the short dimension (width) of the laser beam shaped like a long and narrow beam in terms of microns, and the vertical axis expresses the lower limit of average energy density necessary for annealing in terms of J/cm².

The average energy density is calculated on the basis of the average power density of the beam, that is, a half of the maximum power density shown in FIGS. 4 and 5, and the time required for passage of the beam in the short dimension of the beam on the assumption that a portion exhibiting 13.5% as much as power density in the center of the beam indicates the short dimension of the beam. That is, irradiation energy density is calculated as a product of a half of the maximum power density of the irradiation laser beam and the passage time (short dimension per scanning speed) of the laser beam. In simple thought (of ignoring diffusion of heat to the glass substrate or the like), irradiation energy density can be kept constant if the power density of the laser beam is doubled while the short dimension of the laser beam is halved (i.e. the time of passage of the laser beam is halved). According to this thought, when the scanning speed is constant in FIG. 6, the lower limit of the energy density allowing annealing must be constant regardless of the short dimension of the laser beam, that is, each graphic pattern must be parallel to the X axis.

It is however apparent from the result shown in FIG. 6 that required energy density decreases as the short dimension of the laser beam decreases. It is likewise apparent from FIG. 6 that required energy density decreases as the scanning speed increases. This suggests that diffusion of heat to the substrate can be reduced when reduction in the short dimension of the laser beam or increase in the scanning speed of the laser beam is performed or when both reduction in the short dimension of the laser beam and increase in the scanning speed of the laser beam are performed. That is, this suggests that energy efficiency increases as the short dimension of the laser beam decreases or as the scanning speed of the laser beam increases.

What is meant by this is that the long dimension of the laser beam can be taken large because the short dimension of the laser beam can be reduced. That is, what is meant by this is that the long dimension of the laser beam can be enlarged by remaining power because the power density need not be doubled even in the case where the short dimension of the laser beam is halved. The long dimension of the laser beam is equivalent to a width in which annealing can be performed by laser beam scanning. That is, what is meant by this is that the width allowing annealing in one scanning cycle can be enlarged. Accordingly, throughput can be improved. It is also apparent that increasing the scanning speed is effective in improving the throughput.

When the laser beam can be shaped into a desired size and shape by only the beam shaper 10, the shaped beam can be directly applied on the substrate to perform annealing. When a diffractive optical element is used as the beam shaper 10, it is however difficult to produce a diffractive optical element capable of condensing a beam into a beam diameter of the order of microns (equivalent to the beam width in the direction of the short dimension of the beam in this embodiment) by an existing photo-etching technique. That is, because the accuracy of etching and the number of steps formed by etching are limited, it is considerably difficult to condense light with about two or three times of the wavelength, that is, a wavelength of 532 nm used herein into a light spot with a size of about 1 micron or condense the short dimension of the shaped beam according to this invention into a size of about 1 micron.

What is meant by this is that the short dimension most suitable for laser annealing is limited as described above. Therefore, as shown in FIG. 1, an incident laser beam having a Gaussian distribution is first shaped into a long and narrow beam having a size ranging from several times to tens of times as much as the required short dimension, by the beam shaper 10. Then, the long and narrow beam is reductively projected by the imaging lens 14. If necessary, the rectangular opening slit 11 may be set in the imaged position of the long and narrow beam so that skirt portions of the beam can be shaded to rearrange the beam shape.

The laser beam passed through the rectangular opening slit 11 is reductively projected on a surface of the substrate 13 placed on the stage 12 by the imaging lens 14 while the size of the laser beam is reduced to 1/M (in which M is an integer ranging from about 2 to about 90). For example, after the laser beam is shaped by the beam shaper 10 so that the short dimension of the laser beam on a plane of the rectangular opening slit 11 becomes 15 microns, the size of the shaped beam is reduced to ⅕ by the imaging lens 14 with magnifying power of 5. Alternatively, after the laser beam is shaped by the beam shaper 10 so that the short dimension of the laser beam becomes 60 microns, the size of the shaped beam is reduced to 1/20 by the imaging lens 14 with magnifying power of 20. As a result, a long and narrow laser beam having a short dimension of 3 microns can be applied on a surface of the substrate 13. In this manner, when a laser beam is applied on the substrate 13 in the aforementioned condition while the stage 12 on which the substrate 13 is placed is moved, silicon crystals can be grown laterally in the scanning direction of the laser beam to form belt-like crystal grains.

If the scanning speed is higher than the rate of crystal growth (several m/s), crystals cannot be grown. For this reason, the rate of crystal growth is the upper limit of the scanning speed. If it is further considered that a large-size glass substrate having a size of 1 m square or larger is scanned at a high speed and for a long time (long period), the upper limit of the scanning speed is about 1 m/s (1000 mm/s) in the existing technique.

It is proved from the above description that a silicon thin film having a film thickness of from 40 nm to 200 nm can be annealed most suitably in the condition that the short dimension of the laser beam is selected to be in a range of from 2 to 10 microns, preferably in a range of from 2 to 4 microns to reduce the energy density required for annealing as is obvious from FIG. 6, and that the scanning speed is selected to be in a range of from 300 to 1000 mm/s, preferably in a range of from 500 to 1000 mm/s to widen the power density range required for good annealing as is obvious from FIG. 5.

Incidentally, it is preferable that the long dimension of the laser beam applied on the substrate is smaller than the width of the semiconductor thin film as a subject of irradiation. This is because gathering may occur easily in an end portion of the semiconductor thin film or the region of disordered crystal orientation may be enlarged if the semiconductor thin film is irradiated with the laser beam so that the long dimension of the laser beam is out of the region of the semiconductor thin film after the semiconductor thin film is narrowed by patterning or the like. On the contrary, when the long dimension of the laser beam applied on the substrate is selected to be smaller than the width of the semiconductor thin film as a subject of irradiation, heat can be radiated out of the irradiated region because there is no end portion of the semiconductor thin film in the irradiated region. As a result, gathering hardly occurs and enlargement of the disordered crystal orientation region can be suppressed.

Incidentally, it is preferable from the point of view of achieving good annealing that variation in surface position of the substrate 13 in a direction (Z direction) perpendicular to the principal surface of the substrate 13 is kept small. For example, such variation is caused by a warp of the substrate 13, variation in thickness of the substrate 13, roughness of the film formed on the substrate 13, and so on. Although an automatic focusing mechanism may be provided for this reason, it is difficult to move an optical system or the stage 12 in the Z direction at a high speed when the substrate 13 needs to be scanned at a high speed as described above. It is therefore preferable that, for example, a substrate little in the warp of the substrate and in variation in thickness of the substrate is used so that change in the short dimension (width) of the laser beam projected on the surface of the substrate 13 in accordance with variation in surface position in the Z direction can be kept within 10%, that is, change in average energy density can be kept within 10%.

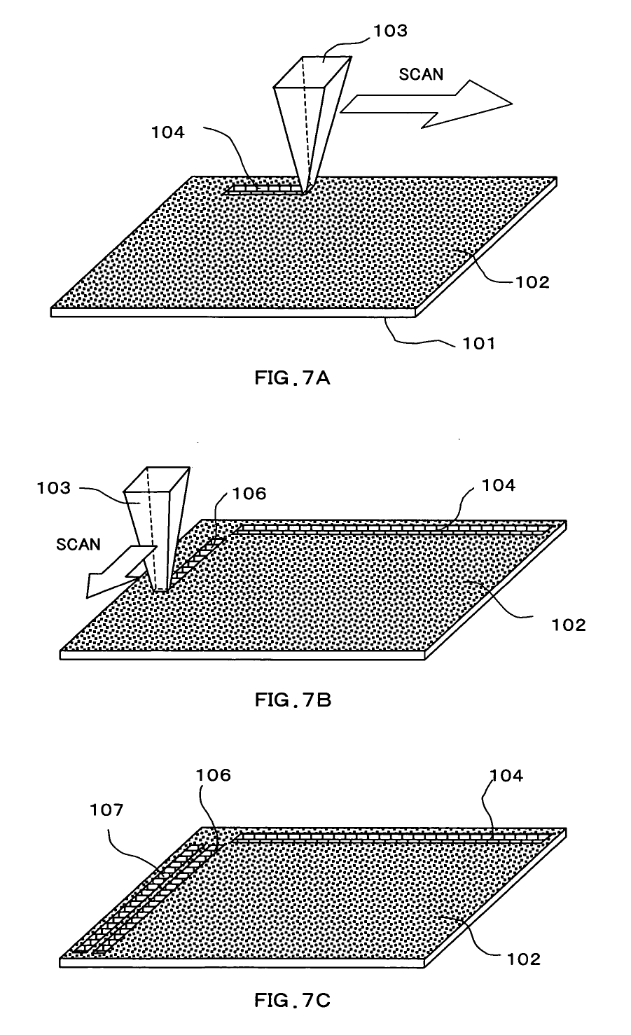

Next, a laser annealing method as an embodiment of the invention executed by the aforementioned laser annealing apparatus will be described with reference to FIGS. 7A to 7C.

FIGS. 7A to 7C are explanatory views showing the laser annealing method according to the embodiment of the invention. In this embodiment, a polycrystalline silicon thin film substrate is used most generally as the substrate 13. The polycrystalline silicon thin film substrate is prepared as follows. An amorphous silicon thin film having a film thickness of from 40 to 200 nm is formed on a principal surface of a glass substrate 101 through an insulating thin film (not shown). The whole surface of the amorphous silicon thin film is scanned by an excimer laser beam or a pulsed solid-state laser beam so as to be crystallized to a polycrystalline silicon thin film 102. The insulating thin film used herein is a film of SiO₂ or SiN or a composite film of SiO₂ and SiN. The polycrystalline silicon thin film 102 obtained by excimer laser or pulsed solid-state laser annealing is used as pixel switching transistors. The invention however may be applied to a substrate having an amorphous silicon film formed thereon if polycrystallization of pixel portions will be executed later.

The substrate 13 having the polycrystalline silicon thin film 102 formed thereon is placed and fixed on the XY stage 12 by a conveyor robot (not shown). Alignment marks are formed on a plurality of places of the polycrystalline silicon thin film substrate 13 by laser irradiation. The alignment marks thus formed are detected to align the substrate 13. The alignment marks may be formed by a photo-etching process or by an ink jet method or the like in advance. Or the alignment marks may be formed by the annealing laser used for annealing or by an alignment mark-forming laser provided separately from the annealing laser when the substrate 13 is placed and fixed on the stage 12.

When a polycrystalline silicon substrate without any alignment mark formed is used, the substrate 13 may be aligned by means of pressing an end surface of the substrate 13 against pins etc. (not shown) placed on the XY stage 12. After laser annealing of predetermined regions is completed in the condition that the substrate 13 is aligned by means of pressing an end surface of the substrate 13 against pins etc. (not shown) placed on the stage 12, alignment marks may be formed in positions having a predetermined relation to the annealed regions by laser beam irradiation or the annealed regions per se may be used as alignment marks.

The alignment marks or the annealed regions per se are satisfactory if they can be used for positioning an exposure photo mask in the first photoresist process (generally, the process of etching the silicon thin film) after the laser annealing process. Alignment marks formed newly by the first photoresist process (etching process) may be used in photoresist processes after the first photoresist process.

After completion of alignment, as shown in FIG. 7A, a drain driver circuit region 104 is first scanned and irradiated with a laser beam 103 in accordance with designed coordinates on the basis of the detected alignment mark position (or end surface of the substrate). The laser beam 3 is extracted with an arbitrary irradiation time width by the modulator 7, shaped into a long and narrow beam by the beam shaper 10 and imaged on the plane of the rectangular opening slit 11. The imaged laser beam is reductively projected on a surface of the substrate by the imaging lens 14 so that the size of the laser beam is reduced to the reciprocal of the magnifying power of the imaging lens. That is, when a lens having magnifying power of 5 is used as the imaging lens, the size of the laser beam is reduced to ⅕. When a lens having magnifying power of 20 is used as the imaging lens, the size of the laser beam is reduced to 1/20.

While the laser beam 103 projected as a long and narrow beam by the imaging lens 14 is applied on the surface of the polycrystalline silicon thin film 102, the XY stage 12 is moved at a high speed. In this manner, the long and narrow beam can be scanned in a direction (i.e. the direction of the short dimension) perpendicular to the direction of the long dimension of the beam so that the region which needs to be annealed can be irradiated with the laser beam. On this occasion, the long and narrow beam is shaped so that the short dimension (width) of the beam is selected to be not larger than 10 μm, preferably in a range of from 2 to 4 μm, while the long dimension of the beam is selected to be in a range of from the order of hundreds of μm to 1 mm in the case of the oscillator output of 10 W though the long dimension of the beam depends on the laser oscillator output. Although the scanning speed depends on the silicon film thickness or the short dimension of the linear beam, the scanning speed preferably used when the short dimension of the laser beam is in a range of from 2 to 4 microns is in a range of from 300 to 1000 mm/s, further preferably in a range of from 500 to 1000 mm/s.

Although this embodiment and FIGS. 4 to 6 have been described on the assumption that the laser beam is scanned in a direction (of the short dimension) perpendicular to the direction of the long dimension of the laser beam, the invention is not limited thereto. When, for example, the scanning direction of the laser beam is selected to be a direction crossing the direction of the long dimension of the laser beam (at any angle inclusive of a right angle), the short dimension explained in FIGS. 4 to 6 can be considered to be replaced by a dimension measured in the scanning direction of the laser beam. When, for example, the scanning direction of the laser beam is perpendicular to the direction of the long dimension of the laser beam, the dimension measured in the scanning direction of the laser beam is equal to the short dimension of the laser beam.

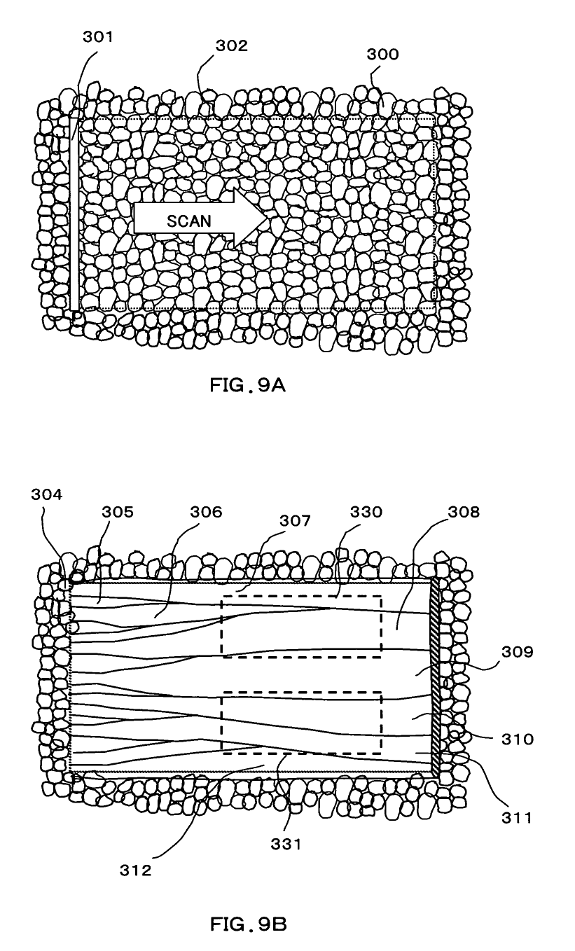

The behavior of the polycrystalline silicon thin film will be described below with reference to FIGS. 9A and 9B in the case where the polycrystalline silicon thin film is irradiated while scanned with a CW laser beam temporally modulated in amplitude and shaped into a long and narrow beam.

FIGS. 9A and 9B are views for explaining a process of irradiating the polycrystalline silicon film substrate with the shaped beam to form belt-like crystals in the substrate. As shown in FIG. 9A, while a polycrystalline silicon film 300 is irradiated with a laser beam 301 condensed into a long and narrow shape, a region 302 is irradiated with the laser beam 301. When the region 302 is irradiated with the laser beam 301 having proper power density, the polycrystalline silicon film in the region 302 irradiated with the laser beam 301 is melted though the polycrystalline silicon film 300 out of the laser-irradiated region 302 remains as it is. Then, the laser beam 301 is moved out (or traveled) the molten silicon to thereby solidify and crystallize the molten silicon rapidly. On this occasion, as shown in FIG. 9B, cooling and solidification of silicon starts at a region first melted in the irradiation start portion. A crystal grain being in contact with the laser-irradiated region 302 serves as a seed crystal. For example, a crystal grain 304 serves as a seed crystal for crystal growth in the scanning direction of the laser beam.

The growth rate of crystal however varies according to the direction of crystal orientation. For this reason, finally, only crystal grains having a direction of crystal orientation exhibiting the highest growth rate can grow continuously. That is, as shown in FIG. 9B, the growth of a crystal grain 305 having a direction of crystal orientation exhibiting a low growth rate is suppressed by the growth of crystal grains 306 and 307 adjacent to the crystal grain 305 and each having a direction of orientation exhibiting a high growth rate. As a result, the crystal growth of the crystal grain 305 stops. The crystal grain 306 having a direction of crystal orientation exhibiting an intermediate growth rate grows continuously but the growth of the crystal grain 306 is suppressed by the growth of crystal grains 307 and 308 each exhibiting a higher growth rate. As a result, the crystal growth of the crystal grain 306 stops. Finally, the crystal grains 307 and 308 having a direction of crystal orientation exhibiting the highest growth rate grow continuously. Incidentally, the crystal grains 307 and 308 cannot grow endlessly. When each crystal grain grows up to a length of about 5 microns to about 50 microns, the growth of the crystal grain is suppressed by the growth of a crystal grain beginning to grow newly or separated into a plurality of crystal grains. For this reason, crystal grains having a width of from 0.2 to 2 microns and a length of from 5 to 50 microns are obtained consequently.

The crystal grains 307, 308, 309, 310, 311 and 312 grown continuously to the last are independent crystal grains in the strict sense. These crystal grains 307, 308, 309, 310, 311 and 312 however substantially have the same direction of crystal orientation. In the melted and re-crystallized portion, silicon crystals are grown laterally to form belt-like crystal grains to thereby form a polycrystalline film. In practice, the polycrystalline film can be regarded as a single crystal (pseudo single crystal). In addition, the surface roughness of the polycrystalline film after laser annealing is not larger than 10 nm. That is, the polycrystalline film is very flat in terms of surface state.

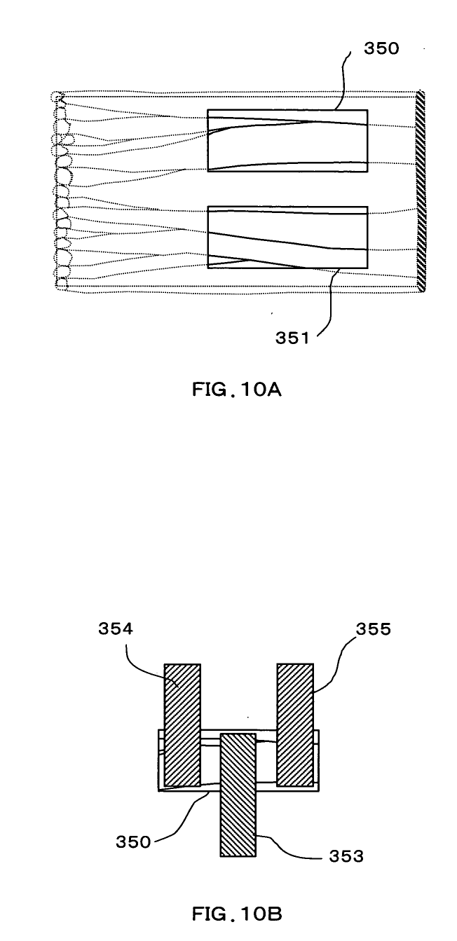

FIGS. 10A and 10B are views for explaining a process of forming thin film transistors from the belt-like crystals formed in FIGS. 9A and 9B. As described above with reference to FIGS. 9A and 9B, when the polycrystalline silicon thin film 300 is irradiated with the laser beam 301, the region 302 irradiated with the laser beam 301 is annealed like islands (tiles) to grow only crystal grains having a specific direction of crystal orientation. As a result, there is formed a region being polycrystalline in the strict sense but having properties close to those of a single crystal. As shown in FIG. 10A, island-like silicon thin film regions 350 and 351 are formed by a photo-etching process executed after annealing. After processes such as a process of diffusing impurities into predetermined regions and a process of forming a gate insulating film, as shown in FIG. 10B, a gate electrode 353, a source electrode 354 and a drain electrode 355 are formed to complete a thin film transistor (TFT).

As shown in FIG. 10B, the belt-like crystal grains can be substantially regarded as a single crystal because a current does not cross grain boundaries when the direction of grain boundaries of the belt-like crystal grains (the direction of crystal growth) is made coincident with the direction of the current. On this occasion, a value of 400 cm²/Vs or higher is obtained as mobility of the silicon film. Typically, a value of 450 cm²/Vs is obtained as mobility of the silicon film.

When an amorphous silicon film is formed on a glass substrate, the same result as described in FIGS. 8A and 8B is obtained. Microcrystals generated in the laser irradiation start portion serve as seed crystals, so that crystals grow laterally in the scanning direction of the laser beam in the same manner as in the case of a polycrystalline silicon film. There is no recognized difference between the case where the laterally grown belt-like crystals are formed from an amorphous state and the case where the laterally grown belt-like crystals are formed from a polycrystalline state.

As shown in FIG. 7A, when the drain driver circuit region 104 is irradiated while scanned with the laser beam 103, the polycrystalline silicon thin film (or amorphous silicon thin film) 102 in the irradiated portion is melted. After the laser beam 103 is moved out (or traveled) the molten silicon, the molten silicon is re-solidified. Crystals in the polycrystalline film remaining in the irradiation start portion serve as seed crystals, so that crystal grains grow laterally in the scanning direction of the laser beam 103 to form a set of belt-like crystal grains which is so called pseudo single crystal. The pseudo single crystal is a set of independent crystal grains in the strict sense but is substantially uniform in terms of direction of crystal orientation. Accordingly, the melted and re-crystallized portion can be substantially regarded as a single crystal.

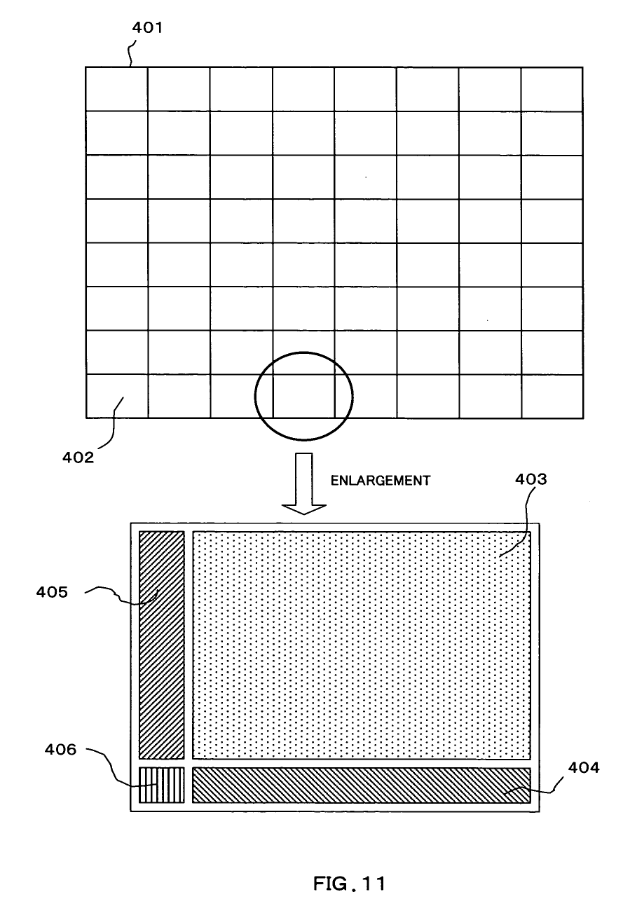

FIG. 11 is a view for explaining a substrate composed of a plurality of panels. Although the glass substrate shown in FIGS. 7A to 7C is composed of a panel, there is an actual situation that a large number of panels 402 are formed in a substrate 401 as shown in FIG. 11. A lower part of FIG. 11 is an enlarged view showing a panel portion. As shown in the lower part of FIG. 11, a pixel region 403, a drain driver circuit region 404, a gate driver circuit region 405 and a peripheral circuit region 406 are formed in the inside of a panel 402. When attention is paid to the drain driver circuit region 404, the on/off control of the laser beam 103 may be repeated by the modulator 7 to form a belt-like crystal region separated into a plurality of blocks though FIG. 7A has shown the case where one panel is continuously irradiated with the laser bream 103.

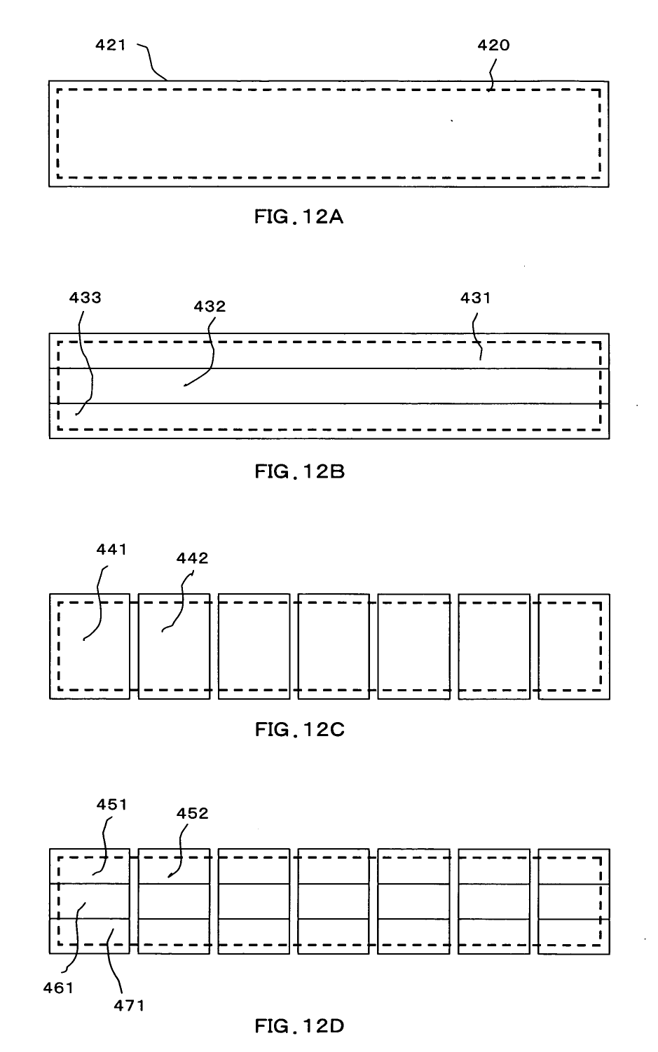

FIGS. 12A to 12D are views for explaining various arrangements of belt-like crystal regions in the case where the drain driver circuit region in one panel is taken as an example. As shown in FIG. 12A, the drain driver circuit region 104 may be provided as a belt-like crystal region 421. Generally, the belt-like crystal region 421 is formed so as to be wider by about 1-50 microns (preferably 10-15 microns) than the drain driver circuit region 420. This is decided by the width of the disordered crystal orientation region in the outermost edge portion of the belt-like crystal region 421, the irradiation position accuracy of the annealing apparatus and the exposure position accuracy in the photo-etching process after annealing.

As shown in FIG. 12B, belt-like crystal regions 431, 432 and 433 may be formed separately by a plurality of scanning cycles (three cycles or a reciprocating motion and a half in FIG. 12B). On this occasion, the first, second and third scanning regions may be set so as to be in contact with one another or may be set so that a space of from 1 to 10 microns or an overlap portion of from 1 to 10 microns is provided between adjacent ones of the scanning regions.

As shown in FIG. 12C, a plurality of belt-like crystal regions 441 may be annealed separately by one scanning cycle while the laser beam is modulated in amplitude by the modulator 7 so that a space of from 1 to 10 microns is provided between adjacent ones of the belt-like crystal regions. Or the plurality of belt-like crystal regions may be annealed alternately by two scanning cycles (one reciprocating motion) so that adjacent belt-like crystal regions 441 and 442 are in contact with each other or an overlap portion of from 1 to 10 microns is provided between the adjacent belt-like crystal regions 441 and 442.

As shown in FIG. 12D, a plurality of belt-like crystal regions 451, 452, etc. may be formed in such a manner that scanning is separated into a plurality of scanning cycles (three cycles or a reciprocating motion and a half in FIG. 12D) while the laser beam is modulated in amplitude by the modulator 7 in each scanning cycle so that a space of from 1 to 10 microns is provided between adjacent ones of the belt-like crystal regions. Or one row of regions may be annealed alternately by two scanning cycles (one reciprocating motion) so that adjacent belt-like crystal regions 451 and 452 are in contact with each other or that an overlap portion of from 1 to 10 microns is provided between the adjacent belt-like crystal regions 451 and 452.

Further, a row of belt-like crystal regions 461 or a row of belt-like crystal regions 471 maybe annealed so that a space or overlap portion is provided between adjacent ones of the belt-like crystal regions or that adjacent ones of the belt-like crystal regions are in contact with each other. When any method is used, the energy density of the laser beam applied on a gap portion between adjacent panels needs to be energy density to turn off the laser beam or stop lateral growth in order to renew crystal growth. The space of from 1 to 10 microns in the outer edge portion of each belt-like crystal region, the overlap portion between adjacent belt-like crystal regions or the gap between adjacent belt-like crystal regions has a crystalline state different from that of each belt-like crystal. For this reason, design/layout must be made so that a transistor is not formed in this region.

After irradiation of the drain driver circuit region 104 with the laser beam is completed, a vessel containing an image rotator (not shown) and disposed in the rear of the beam shaper is rotated so that the laser beam shaped into a long and narrow beam is rotated by 90 degrees around the optical axis while the scanning direction of the stage is changed by 90 degrees or the beam shaper is rotated by 90 degrees around the optical axis while the scanning direction is changed by 90 degrees. Consequently, as shown in FIG. 7B, the gate driver circuit region 106 can be irradiated while scanned with the laser beam 103 shaped into a long and narrow beam in the same manner as the case where the drain driver circuit region 104 is irradiated with the laser beam. It is a matter of course that re-alignment based on the alignment marks is required after the substrate is rotated.

Or the stage may be moved in one direction while the substrate is rotated by 90 degrees without rotation of the laser beam shaped into a long and narrow beam. In brief, the scanning direction needs to be relatively rotated by 90 degrees. When a silicon film of high mobility is necessary only for the drain driver circuit region, the invention need not be applied to the gate driver circuit region and other peripheral portions as will be described later. In this case, the gate driver circuit region and other peripheral portions are formed from a silicon film annealed by excimer laser or pulsed solid-state laser irradiation.

Although FIG. 7B has shown the case where one panel is irradiated with the laser beam 103 continuously, the on/off control of the laser beam 103 may be repeated by the modulator 7 to separate the belt-like crystal region into a plurality of blocks in the same manner as in the case where the drain driver circuit region is annealed. Incidentally, the energy density of the laser beam at least applied on the gap portion between panels is set as energy density to turn off the laser beam or stop lateral growth in order to renew crystal growth. Although FIG. 7B has shown the case where irradiation of the gate driver circuit region 106 with the laser beam is completed by one scanning cycle, a plurality of scanning cycles may be used according to necessity if the whole of a predetermined region cannot be annealed by one scanning cycle because the width of irradiation in one scanning cycle (i.e. the long dimension of the linearly shaped beam) depends on the output of the laser beam 103. In this case, annealing can be made in the same manner as in the case where the drain driver circuit region is annealed.

Then, if necessary, as shown in FIG. 7C, the stage is scanned while the peripheral portion 107 such as an interface circuit portion is irradiated with the laser beam 103 in the same manner as in the case where the drain driver circuit region 104 and the gate driver circuit region 106 are irradiated with the laser beam. Thus, the laser annealing process for the substrate 13 is completed. After completion of the process, the substrate 13 is conveyed to the outside by a conveyor robot etc. (not shown) and a new substrate is conveyed into the annealing apparatus so that the annealing process for the new substrate is continued.

By the aforementioned method, the drain driver circuit region 104 and the gate driver circuit region 106 of an amorphous or polycrystalline silicon film formed on a glass substrate can be irradiated with a long and narrow beam obtained by shaping a temporally modulated CW laser beam. If necessary, the other peripheral circuit region 107 can be irradiated with the long and narrow beam. By the irradiation, the silicon film is melted. When the laser beam is moved out (or traveled) the molten silicon, the molten silicon is re-solidified so that crystal grains grow laterally in the scanning direction of the laser beam to thereby form belt-like crystal regions. The size of each crystal grain formed on this occasion varies according to the thickness of the silicon film and the condition for laser irradiation. Generally, the size of each crystal grain is in a range of from about 5 to 50 microns in the scanning direction of the laser beam and in a range of from about 0.2 to 2 microns in a direction perpendicular to the scanning direction of the laser beam. When the source-drain direction of a thin film transistor (TFT) formed on the glass substrate is made coincident with the direction of crystal growth (i.e. the scanning direction of the laser beam), a transistor of high performance can be formed. Accordingly, the laser annealing method and laser annealing apparatus according to the invention can be applied to production of various display devices represented by a liquid crystal or organic EL display device using TFTs.

Although the embodiments have been described on the case where a CW laser beam is used as the laser beam 3, the invention may be applied to the case where a pulsed laser beam is used as the laser beam 3.

While we have shown and described several embodiments in accordance with our invention, it should be understood that disclosed embodiments are susceptible of changes and modifications without departing from the scope of the invention. Therefore, we do not intend to be bound by the details shown and described herein but intend to cover all such changes and modifications a fall within the ambit of the appended claims.

1. A laser annealing apparatus comprising: a laser oscillator for generating a laser beam; a beam shaper for shaping the oscillated laser beam into a long and narrow beam; and a stage for placing and moving a substrate to be irradiated with the laser beam shaped into a long and narrow beam, wherein: said beam shaper is made of either a diffractive optical element or a combination of a Powell's lens and a cylindrical lens; and said laser annealing apparatus further comprises an imaging lens by which the laser beam shaped into a long and narrow beam by said beam shaper is reductively projected on said substrate so that the short dimension of the laser beam is reduced to 2-10 microns when the laser beam is applied on said substrate.

2. A laser annealing apparatus according to claim 1, wherein said laser oscillator is a laser oscillator for generating a continuous-wave (CW) laser beam.

3. A laser annealing apparatus comprising: a solid-state laser oscillator for generating a CW laser beam; a modulator for temporally amplitude modulating the oscillated laser beam; a beam shaper for shaping the laser beam into a long and narrow beam; and a stage for placing and moving a substrate to be irradiated with the laser beam temporally modulated in amplitude and shaped into a long and narrow beam, wherein: said beam shaper is made of either a diffractive optical element or a combination of a Powell's lens and a cylindrical lens; and said laser annealing apparatus further comprises an imaging lens by which the laser beam shaped into a long and narrow beam by said beam shaper is reductively projected on said substrate so that the short dimension of the laser beam is reduced to 2-10 microns when the laser beam is applied on said substrate.

4. A laser annealing method comprising the steps of: placing a substrate having an amorphous or polycrystalline silicon film formed on its one principal surface, on a stage; and irradiating a required region of said amorphous or polycrystalline silicon film on said substrate with a laser beam shaped into a long and narrow beam while scanning said required region in a direction crossing the direction of the long dimension of the shaped long and narrow laser beam, wherein: the direction of the long dimension of the shaped long and narrow laser beam applied on said substrate is smaller than the width of said amorphous or polycrystalline silicon film formed on said substrate; and the size of the laser beam measured in the scanning direction of the laser beam is in a range of from 2 to 10 microns.

5. A laser annealing method according to claim 4, wherein said laser beam is a CW laser beam.

6. A laser annealing method comprising the steps of: placing a substrate having an amorphous or polycrystalline silicon film formed on its one principal surface, on a stage; and irradiating a required region of said amorphous or polycrystalline silicon film on said substrate with a CW laser beam temporally modulated in amplitude and shaped into along and narrow beam while scanning said required region in a direction crossing the direction of the long dimension of the shaped long and narrow laser beam, wherein: the direction of the long dimension of the shaped long and narrow laser beam applied on said substrate is smaller than the width of said amorphous or polycrystalline silicon film formed on said substrate; and the size of the laser beam measured in the scanning direction of the laser beam is in a range of from 2 to 10 microns.

7. A laser annealing method according to claim 4, wherein the size of the shaped long and narrow laser beam applied on said substrate and measured in the scanning direction is in a range of from 2 to 4 microns.

8. A laser annealing method according to claim 6, wherein the size of the shaped long and narrow laser beam applied on said substrate and measured in the scanning direction is in a range of from 2 to 4 microns.

9. A laser annealing method according to claim 4, wherein the scanning speed of the laser beam is in a range of from 300 to 1000 mm/s.

10. A laser annealing method according to claim 6, wherein the scanning speed of the laser beam is in a range of from 300 to 1000 mm/s.

11. A laser annealing method according to claim 4, wherein the scanning speed of the laser beam is in a range of from 500 to 1000 mm/s.

12. A laser annealing method according to claim 6, wherein the scanning speed of the laser beam is in a range of from 500 to 1000 mm/s.

13. A laser annealing method according to claim 4, wherein said substrate is scanned while irradiated with the laser beam to thereby transform said amorphous or polycrystalline silicon film formed on said substrate surface into a polycrystalline silicon film laterally grown like belts in the scanning direction of the laser beam.

14. A laser annealing method according to claim 6, wherein said substrate is scanned while irradiated with the laser beam to thereby transform said amorphous or polycrystalline silicon film formed on said substrate surface into a polycrystalline silicon film laterally grown like belts in the scanning direction of the laser beam.
